(19) United States
(12) Patent Application Publication
(10) Pub. No.: US 2025/0022900 A1
(43) Pub. Date: Jan. 16, 2025

(54) IMAGE SENSOR AND MANUFACTURING METHOD THEREOF

(71) Applicant: SAMSUNG ELECTRONICS CO., LTD., Suwon-si (KR)

(72) Inventors: Jinyoung KIM, Suwon-si (KR); Junghyun Kim, Suwon-si (KR); Junsik Lee, Suwon-si (KR); Jonghoon Park, Suwon-si (KR); Yun Ki Lee, Suwon-si (KR)

(73) Assignee: SAMSUNG ELECTRONICS CO.,LTD., Suwon-si (KR)

(21) Appl. No.: 18/618,477

(22) Filed: Mar. 27, 2024

(30) Foreign Application Priority Data
Jul. 14, 2023 (KR) 10-2023-0091954

(51) Int. Cl. H01L 27/146

(52) U.S. Cl. CPC H01L 27/1463; H01L 27/14645; H01L 27/14683

(57) ABSTRACT

An image sensor includes: a substrate including a first side and a second side facing the first side; pixels including a photoelectric conversion layer in the substrate and a transistor on the first side of the substrate; and a pixel separating pattern between the pixels, wherein the pixel separating pattern includes a first separating pattern, a second separating pattern, and a third separating pattern, the second separating pattern is conductive, and the first separating pattern and the third separating pattern are non-conductive, the second separating pattern is nearer the first side of the substrate than is the third separating pattern, and a first end of the first separating pattern, a first end of the second separating pattern, and a first end of the third separating pattern are on the second side of the substrate.

### CROSS-REFERENCE TO RELATED APPLICATION

This application claims priority to and the benefit of Korean Patent Application No. 10-2023-0091954, filed on Jul. 14, 2023, in the Korean Intellectual Property Office, the contents of which are incorporated by reference herein its entirety.

### BACKGROUND

### 1. Field

The disclosure relates to an image sensor and a manufacturing method thereof.

### 2. Description of Related Art

An image sensor is a semiconductor device for converting optical images into electrical signals. The image sensor may be classified into a charge coupled device (CCD) type and a complementary metal oxide semiconductor (CMOS) type. The CMOS-type image sensor may be referred to as a CMOS image sensor (CIS). The CIS has pixels arranged in a two-dimensional way. The respective pixels include a photodiode (PD). The photodiode converts incident light into electric signals.

Pixel separating patterns may be disposed among the respective pixels. The pixel separating patterns may have a lattice structure in a plan view and may partition the respective pixels.

### SUMMARY

Embodiments of the disclosure provide an image sensor for reducing a dark current and increasing sensitivity, and a manufacturing method thereof.

According to an aspect of an example embodiment, an image sensor includes: a substrate including a first side and a second side facing the first side; pixels including a photoelectric conversion layer in the substrate and a transistor on the first side of the substrate; and a pixel separating pattern between the pixels, wherein the pixel separating pattern includes a first separating pattern, a second separating pattern, and a third separating pattern, the second separating pattern is conductive, and the first separating pattern and the third separating pattern are non-conductive, the second separating pattern is nearer the first side of the substrate than is the third separating pattern, and a first end of the first separating pattern, a first end of the second separating pattern, and a first end of the third separating pattern are on the second side of the substrate.

According to an aspect of an example embodiment, an image sensor includes: a substrate including a first side and a second side facing the first side; pixels each including a photoelectric conversion layer in the substrate and a transistor on the first side of the substrate; and a pixel separating pattern between the pixels, wherein the pixel separating pattern includes a first separating pattern including silicon oxide, a second separating pattern including a polycrystalline semiconductor, and a third separating pattern including silicon nitride, wherein the second separating pattern is nearer the first side of the substrate than is the third separating pattern, and edges of the third separating pattern, the second separating pattern on edges of the third separating pattern, and the first separating pattern contacting the second separating pattern are on the second side of the substrate.

According to an aspect of an example embodiment, a method for manufacturing an image sensor, includes: providing a substrate including a first side, a second side, and a first trench disposed on the first side; forming a first separating pattern on an edge of the first trench of the substrate; forming a second portion of a second separating pattern in the first trench on the first separating pattern; forming a third separating pattern in the first trench; forming a first portion of the second separating pattern overlapping the third separating pattern in a thickness direction of the substrate in the first trench; etching the first side; and etching the second side, wherein the etching of the second side includes exposing a first end of the first separating pattern, a first end of the second separating pattern, and a first end of the third separating pattern on the second side of the substrate.

### BRIEF DESCRIPTION OF THE DRAWINGS

The above and other aspects, features, and advantages of certain embodiments of the present disclosure will be more apparent from the following description taken in conjunction with the accompanying drawings, in which:

FIG. 1 shows a block diagram of an image sensor according to an embodiment;

FIG. 2 shows a circuit diagram of a pixel included in an image sensor according to an embodiment;

FIG. 3 shows a top plan view of an image sensor according to an embodiment;

FIG. 4 shows a cross-sectional view with respect to a line A-A′ of FIG. 3;

FIG. 5 shows an enlarged portion marked as B in FIG. 4;

FIG. 6 shows an enlarged portion marked as A in FIG. 5;

FIG. 7 shows a partial shape of a pixel separating pattern on a second side of a first substrate in a plan view;

FIG. 8 shows a same portion as FIG. 6 according to an embodiment;

FIG. 9 shows a same portion as FIG. 6 according to an embodiment;

FIG. 10 shows a same portion as FIG. 6 according to an embodiment;

FIG. 11 shows a process for manufacturing an image sensor according to an embodiment;

FIG. 12 shows a process for manufacturing an image sensor according to an embodiment;

FIG. 13 shows a process for manufacturing an image sensor according to an embodiment;

FIG. 14 shows a process for manufacturing an image sensor according to an embodiment;

FIG. 15 shows a process for manufacturing an image sensor according to an embodiment;

FIG. 16 shows a process for manufacturing an image sensor according to an embodiment;

FIG. 17 shows a process for manufacturing an image sensor according to an embodiment;

FIG. 18 shows a process for manufacturing an image sensor according to an embodiment;

FIG. 19 shows a process for manufacturing an image sensor according to an embodiment;

FIG. 20 shows a process for manufacturing an image sensor according to an embodiment; and

FIG. 21 shows a process for manufacturing an image sensor according to an embodiment.

### DETAILED DESCRIPTION

Example embodiments of the disclosure will be described more fully hereinafter with reference to the accompanying drawings. As those skilled in the art would realize, the described embodiments may be modified in various different ways, all without departing from the spirit or scope of the disclosure.

Parts that are irrelevant to the description will be omitted to clearly describe the disclosure, and the same elements will be designated by the same reference numerals throughout the specification.

The size and thickness of each configuration shown in the drawings are arbitrarily shown for better understanding and ease of description, but the disclosure is not limited thereto. In the drawings, the thickness of layers, films, panels, regions, etc., are enlarged for clarity. The thicknesses of some layers and areas are exaggerated for convenience of explanation.

It will be understood that when an element such as a layer, film, region, or substrate is referred to as being “on” another element, it can be directly on the other element or intervening elements may also be present. In contrast, when an element is referred to as being “directly on” another element, there are no intervening elements present. The word “on” or “above” means positioned on or below the object portion, and does not necessarily mean positioned on the upper side of the object portion based on a gravitational direction.

Unless explicitly described to the contrary, the words “comprise” and “include”, and variations such as “comprises,” “comprising,” “includes,” and “including,” will be understood to imply the inclusion of stated elements but not the exclusion of any other elements.

The phrase “in a plan view” means viewing an object portion from the top, and the phrase “in a cross-sectional view” means viewing a cross-section of which the object portion is vertically cut from the side.

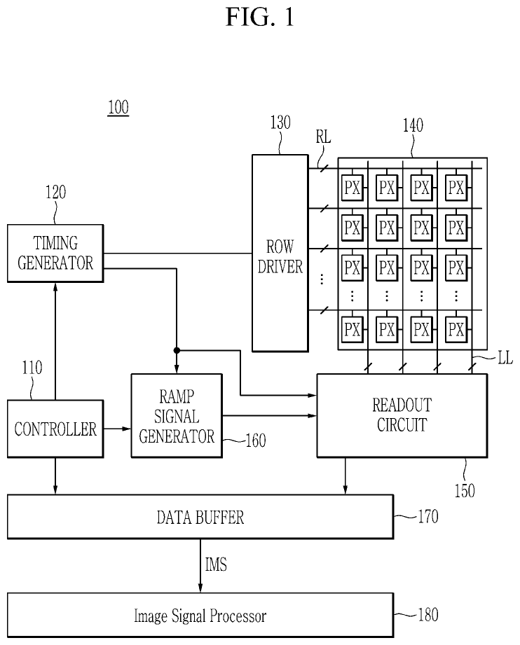

FIG. 1 shows a block diagram of an image sensor according to an embodiment.

Referring to FIG. 1, the image sensor 100 may include a controller 110, a timing generator 120, a row driver 130, a pixel array 140, a readout circuit 150, a ramp signal generator 160, a data buffer 170, and an image signal processor 180. In an embodiment, the image signal processor 180 may be disposed outside the image sensor 100.

The image sensor 100 may convert light received from an outside into electric signals and may generate image signals. The image signal IMS may be provided to the image signal processor 180.

The image sensor 100 may be mounted on an electronic device having an image or light sensing function. For example, the image sensor 100 may be mounted on the electronic device, such as a camera, a smartphone, a wearable device, an Internet of Things (IoT) device, a home appliance, a tablet personal computer, a personal digital assistant (PDA), a portable multimedia player (PMP), a global positioning system (or a navigator), a drone, or an advanced drivers assistance system (ADAS). Alternatively, the image sensor 100 may be mounted on the electronic device provided as a component in a vehicle, furniture, manufacturing facility, doors, or various measurement devices.

The controller 110 may control respective constituent elements 120, 130, 150, 160, and 170 included in the image sensor 100. The controller 110 may control operation timings of the respective constituent elements 120, 130, 150, 160, and 170 by using control signals. In an embodiment, the controller 110 may receive a mode signal indicating an imaging mode from the application processor, and control the image sensor 100 as a whole based on the received mode signal. For example, the application processor may determine the imaging mode of the image sensor 100 according to various scenarios such as illuminance of an imaging environment, resolution settings by a user, a sensed or trained state, and may provide a determined result to the controller 110 as a mode signal. The controller 110 may control pixels of the pixel array 140 to output pixel signals according to the imaging mode, the pixel array 140 may output pixel signals for the respective pixels or pixel signals for some of the pixels, and the readout circuit 150 may sample and process the pixel signals received from the pixel array 140. The timing generator 120 may generate a signal that is a reference for an operation timing of the components of the image sensor 100. The timing generator 120 may control the timings of the row driver 130, the readout circuit 150, and the ramp signal generator 160. The timing generator 120 may provide control signals for controlling the timings of the row driver 130, the readout circuit 150, and the ramp signal generator 160.

The pixel array 140 may include pixels PX, and row lines RL and column lines LL respectively connected to the pixels PX. In an embodiment, the respective pixels PX may include at least one or more photoelectric conversion devices. The photoelectric conversion device may detect incident light and may convert the incident light into electrical signals, that is, analog pixel signals according to the amount of light. The photoelectric conversion device may be a photodiode and a pinned diode. Further, the photoelectric conversion device may be a single-photon avalanche diode (SPAD) applied to a 3D sensor pixel. Levels of the analog pixel signals output by the photoelectric conversion device may be proportional to the amount of charges output from the photoelectric conversion device. That is, the levels of the analog pixel signals output from the photoelectric conversion device may be determined according to the amount of light received into the pixel array 140.

The row lines RL may extend in the first direction and may be connected and may be connected to the pixel PXs disposed in the first direction. For example, the control signal output to the row line RL from the row driver 130 may be transmitted to a gate of the transistor of the pixels PX connected to the corresponding row line RL. The column line LL may extend in a second direction traversing the first direction and may be connected to the pixel PXs disposed in the second direction. The pixel signals output from the pixels PX may be transmitted to the readout circuit 150 through the column lines LL.

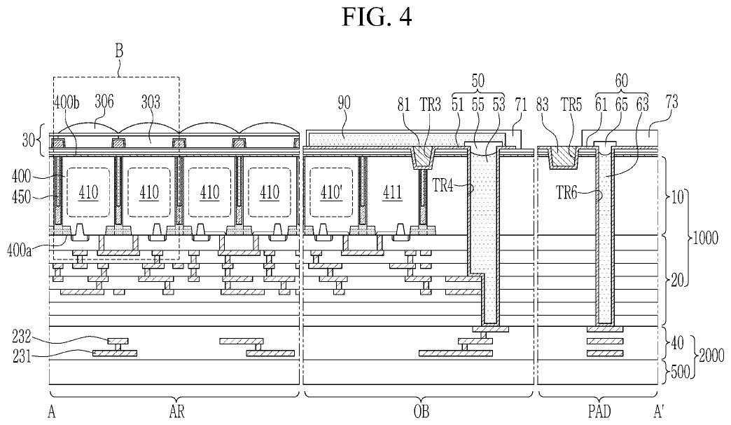

A color filter layer and a micro lens layer may be disposed on the pixel array 140. The micro lens layer may include micro lenses, and the micro lenses may be respectively disposed on an upper portion of at least one pixel PX. The color filter layer may include red, green, and blue color filters, and may further include a white color filter. Regarding one pixel PX, one color filter of one color may be disposed between the pixel PX and the corresponding micro lens. Detailed structures of the color filter layer and the micro lens layer will be described later with reference to FIG. 4.

The row driver 130 may generate control signals for driving the pixel array 140 in response to the control signal of the timing generator 120, and may provide the control signals to the pixels PX of the pixel array 140 through the row lines RL. In an embodiment, the row driver 130 may control the pixel PX to detect incident light for each row line unit. The row line unit may include at least one row line RL. For example, the row driver 130 may provide a transmission signal TS, a reset signal RS, and a selection signal SEL to the pixel array 140, which will be described later.

The readout circuit 150 may convert the pixel signals (or electrical signals) from the pixels PXs connected to the row line RL selected from among the pixels PX into pixel values indicating the amount of light in response to the control signal from the timing generator 120. The readout circuit 150 may convert the pixel signal output through the corresponding column line LL into the pixel value. For example, the readout circuit 150 may convert the pixel signal into the pixel value by comparing the ramp signal and the pixel signal. The pixel value may be image data with bits. In detail, the readout circuit 150 may include a selector, comparators, and counter circuits.

The ramp signal generator 160 may generate a reference signal and may transmit the same to the readout circuit 150.

The ramp signal generator 160 may include a current source, a resistor, and a capacitor. The ramp signal generator 160 may adjust a ramp voltage, which is a voltage applied to the ramp resistor, by adjusting a current magnitude of a variable current source or resistance of a variable resistor, thereby generating the ramp signals falling or rising in a slope determined according to the magnitude of current of the variable current source or the resistance of the variable resistor.

The data buffer 170 may store the pixel values of the pixels PX connected to the selected column line LL transmitted from the readout circuit 150, and may output the stored pixel values in response to an enable signal from the controller 110.

The image signal processor 180 may perform image signal processing on the image signal received from the data buffer 170. For example, the image signal processor 180 may receive image signals from the data buffer 170, and may synthesize the received image signals to generate one image.

In an embodiment, the pixels may be combined in an M*N (here M and N are integers that is equal to or greater than 2) form to configure a unit pixel group. The M*N form may represent that M-numbered pixels are arranged in an arrangement direction of the column line LL and N-numbered pixels are arranged in an arrangement direction of the row line RL. For example, one unit pixel group may include the pixels arranged in the 2*2 form, and one unit pixel group may output one analog pixel signal. The embodiment to be described below may not be limited to one pixel but may be applied to the unit pixel group.

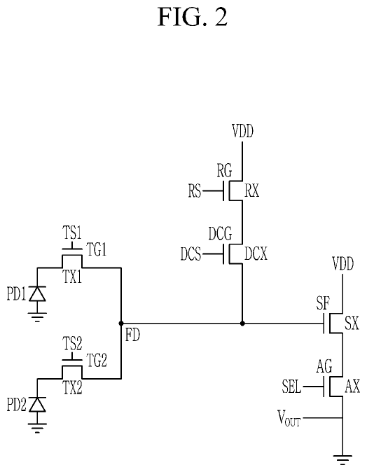

FIG. 2 shows a circuit diagram of a pixel included in an image sensor according to an embodiment.

Referring to FIG. 2, one pixel may include photoelectric conversion devices PD1 and PD2. The respective photoelectric conversion devices PD1 and PD2 may perform a photoelectric conversion function. As shown in FIG. 2, the photoelectric conversion devices PD1 and PD2 may be connected to one floating diffusion region FD. FIG. 2 shows that two photoelectric conversion devices are connected to one floating diffusion region FD, which is an example, and the number of the photoelectric conversion devices connected to the floating diffusion region FD is changeable depending on embodiments.

The first photoelectric conversion device PD1 will be mainly described, and the description is identically applied to the photoelectric conversion device PD2.

The first photoelectric conversion device PD1 may generate charges according to the amount of received light, and may store the charges. The first photoelectric conversion device PD1 may include an anode connected to a ground and a cathode connected to a first end of the first transmission transistor TX1. A first transmission signal TS1 may be supplied to a gate TG1 of the first transmission transistor TX1, and the first end of the first transmission transistor TX1 may be connected to the floating diffusion region FD. When the first transmission transistor TX1 is turned on by the first transmission signal TS1, the charges stored in the first photoelectric conversion device PD1 may be transmitted to the floating diffusion region FD. The floating diffusion region FD may sustain the charges transmitted from the photoelectric conversion device PD.

The transmission transistors TX1 and TX2 may include gate electrodes TG1 and TG2 connected between one of the photoelectric conversion devices PD1 and PD2 and the floating diffusion region FD and receiving the transmission signals TS1 and TS2. For example, the first transmission transistor TX1 may include the gate electrode TG1 connected between the first photoelectric conversion device PD1 and the floating diffusion region FD and receiving the first transmission signal TS1. The number of the transmission transistors TX1 and TX2 may be equal to the number of the photoelectric conversion devices PD1 and PD2.

A reset transistor RX may include a gate electrode RG connected between the power source voltage VDD and the floating diffusion region FD and receiving the reset signal RS.

The reset transistor RX may periodically reset the charges stored in the floating diffusion region FD. A drain electrode of the reset transistor RX may be connected to a source electrode of a dual conversion transistor DCX, and the source electrode may be connected to a power source voltage VDD. When the reset transistor RX is turned on, the power source voltage VDD connected to the source electrode of the reset transistor RX may be applied to the floating diffusion region FD. Therefore, when the reset transistor RX is turned on, the charges stored in the floating diffusion region FD may be discharged, and the floating diffusion region FD may be reset.

The dual conversion transistor DCX may include a gate electrode DCG disposed between the reset transistor RX and the floating diffusion region FD and receiving a dual conversion signal DCS. The dual conversion transistor DCX may reset the floating diffusion region FD together with the reset transistor RX. Depending on embodiments, the dual conversion transistor DCX may be omitted.

A drain electrode of the dual conversion transistor DCX may be connected to the floating diffusion region FD, and a source electrode of the dual conversion transistor DCX may be connected to the drain electrode of the reset transistor RX. When the reset transistor RX and the dual conversion transistor DCX are turned on, the power source voltage VDD connected to the source electrode of the reset transistor RX may pass through the dual conversion transistor DCX and may be applied to the floating diffusion region FD. Therefore, the charges stored in the floating diffusion region FD may be discharged and the floating diffusion region FD may be reset.

The amplification transistor SX may output the pixel signal according to the voltage of the floating diffusion region FD. A gate SF of the amplification transistor SX may be connected to the floating diffusion region FD, the power source voltage VDD may be supplied to the source electrode of the amplification transistor SX, and a drain electrode of the amplification transistor SX may be connected to a first end of the selection transistor AX. The amplification transistor SX may configure a source follower circuit, and may output a voltage at a level that corresponds to the charges stored in the floating diffusion region FD as a pixel signal.

When the selection transistor AX is turned on by a selection signal SEL, the pixel signal from the amplification transistor SX may be transmitted to the readout circuit. The selection signal SEL may be applied to a gate electrode AG of the selection transistor AX, and a drain electrode of the selection transistor AX may be connected to an output wire Vout for outputting pixel signals.

An operation of the image sensor will now be described with reference to FIG. 2. While light is blocked, the power source voltage VDD is applied to the drain electrode of the reset transistor RX and the drain electrode of the amplification transistor SX, and the reset transistor RX and the dual conversion transistor DCX are turned on to discharge the charges remaining in the floating diffusion region FD. When the reset transistor RX is turned to Off and light is input to the photoelectric conversion devices PD1 and PD2 from the outside, pairs of electrons and holes are generated by the photoelectric conversion devices PD1 and PD2. The holes represent a p-type impurity region of the photoelectric conversion devices PD1 and PD2, and the electrons move to an n-type impurity region and are stored therein. When the transmission transistors TX1 and TX2 are turned to On, the charges such as the electrons and the holes are transmitted to the floating diffusion region FD and are stored therein. A gate bias of the amplification transistor SX is changed in proportion to the amount of the stored charges, thereby changing a source potential of the amplification transistor SX. At this time, when the selection transistor AX is turned to On, the signal by charges is read through the output wire Vout.

The wire may be electrically connected to at least one of the gate electrodes TG1 and TG2 of the transmission transistors TX1 and TX2, the gate electrode SF of the amplification transistor SX, the gate electrode DCG of the dual conversion transistor DCX, the gate electrode RG of the reset transistor RX, and the gate electrode AG of the selection transistor AX. The wire may include a power source voltage transmitting wire for applying the power source voltage VDD to the source electrode of the reset transistor RX or the source electrode of the amplification transistor SX. The wire may include an output wire Vout connected to the selection transistor AX.

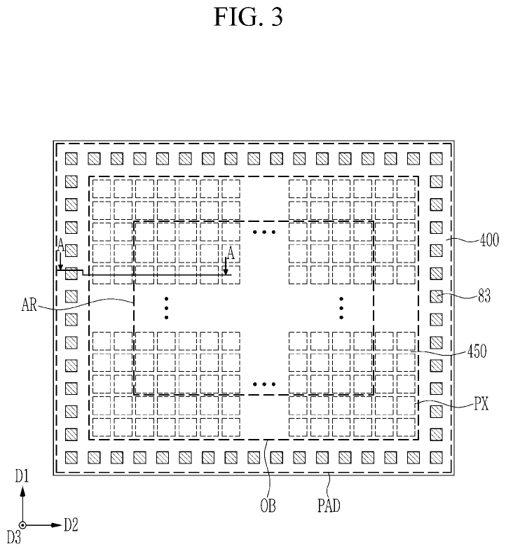

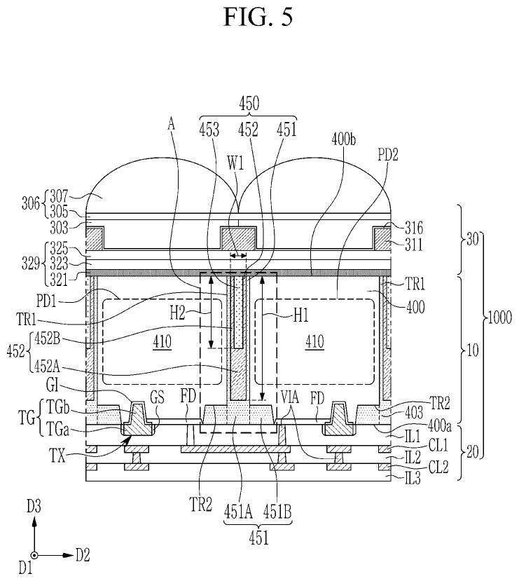

FIG. 3 shows a top plan view of an image sensor according to an embodiment. FIG. 4 shows a cross-sectional view with respect to a line A-A′ of FIG. 3. FIG. 5 shows an enlarged portion marked as B in FIG. 4.

Referring to FIG. 3 to FIG. 5, the image sensor according to the present embodiment may include a sensor chip 1000 and a logic chip 2000. The sensor chip 1000 may include a photoelectric conversion layer 10, a first wire region 20, and a light transmitting layer 30. The photoelectric conversion layer 10 may include a first substrate 400, a pixel separating pattern 450, and a photoelectric conversion region 410 disposed in the first substrate 400. Light input from the outside may be converted into an electrical signal in the photoelectric conversion region 410.

Referring to FIG. 3, the first substrate 400 may include a pixel array region AR, an optical black region OB, and a pad region PAD on a plane. The pixel array region AR may be disposed in a center region of the first substrate 400 on the plane. The pixel array region AR may include pixels PX. The pixel PX may output a photoelectrical signal from the incident light. The pixel PX may be disposed in a row in parallel to a first direction D1 and a column in parallel to a second direction D2.

The pad region PAD may be disposed on an edge of the first substrate 400 and may surround the pixel array region AR. Pad terminals 83 may be disposed in the pad region PAD. The pad terminals 83 may output electrical signals generated by the pixel PX to the outside. Alternatively, the external electrical signals or voltages may be transmitted to the pixel PX through the pad terminals 83. As the pad region PAD is disposed on the edge of the first substrate 400, the pad terminals 83 may be easily connected to the outside.

The optical black region OB may be disposed between the pixel array region AR and the pad region PAD of the first substrate 400. The optical black region OB may surround the pixel array region AR. The optical black region OB may include dummy regions 411. Signals generated by the dummy regions 411 may be used as information for removing processing noise.

Referring to FIG. 4 to FIG. 5, the image sensor may include a photoelectric conversion layer 10, a gate electrode TG of the transmission transistor, a first wire region 20, and a light transmitting layer 30. The photoelectric conversion layer 10 may include a first substrate 400 and a pixel separating pattern 450. The gate electrode RG of the reset transistor RX, the gate electrode DCG of the dual conversion transistor DCX, the gate electrode SF of the amplification transistor SX, and the gate electrode AG of the selection transistor AX shown in FIG. 2 may be disposed on a same layer as the gate electrode TG of the transmission transistor. This is, however, an example, and depending on embodiments, the gate electrode RG of the reset transistor RX, the gate electrode DCG of the dual conversion transistor DCX, the gate electrode SF of the amplification transistor SX, and the gate electrode AG of the selection transistor AX may be disposed on a different substrate from the gate electrode TG of the transmission transistor and may be electrically connected to the same.

The sensor chip 1000 of the pixel array region AR will now be described with reference to FIG. 5. The sensor chip 1000 includes a first substrate 400. The first substrate 400 may include a first side 400a and a second side 400b facing each other. Light may be input to the second side 400b of the first substrate 400. The first wire region 20 may be disposed on the first side 400a of the first substrate 400, and the light transmitting layer 30 may be disposed on a second side 400b of the first substrate 400. The first substrate 400 may be a semiconductor substrate or a silicon on insulator (SOI) substrate. For example, the semiconductor substrate may, for example, include a silicon substrate, a germanium substrate, and a silicon-germanium substrate. The first substrate 400 may include impurities of a first conductive type. For example, the impurities of the first conductive type may be p-type impurities such as aluminum (Al), boron (B), indium (In), and/or gallium (Ga).

Referring to FIG. 3 together, the first substrate 400 may include pixels PX defined by the pixel separating pattern 450. The pixels PX may be arranged in a matrix format in the first direction D1 and the second direction D2 traversing each other. The first substrate 400 may include a photoelectric conversion region 410.

The photoelectric conversion region 410 may perform same functions and roles as the photoelectric conversion devices PD1 and PD2 shown in FIG. 2. FIG. 4 shows the first photoelectric conversion device PD1 and the second photoelectric conversion device PD2.

The photoelectric conversion region 410 may be a region to which impurities of a second conductive type are doped in the first substrate 400. The impurities of a second conductive type may have a conductive type that is opposite to the impurities of first conductive type. The impurities of a second conductive type may include n-type impurities such as phosphorus, arsenide, bismuth, and/or antimony. For example, the photoelectric conversion region 410 may include a first region disposed near the first side 400a and a second region disposed near the second side 400b. The first region and the second region of the photoelectric conversion region 410 may have differences of impurity concentration. Therefore, the photoelectric conversion region 410 may have a potential slope between the first side 400a and the second side 400b of the first substrate 400. For another example, the photoelectric conversion region 410 may not have a potential slope between the first side 400a and the second side 400b of the first substrate 400.

The first substrate 400 and the photoelectric conversion region 410 may configure a photodiode. That is, the photodiode may be configured by a p-n junction between the first substrate 400 of the first conductive type and the photoelectric conversion region 410 of the second conductive type. The photoelectric conversion region 410 configuring the photodiode may generate and store photocharges in proportion to intensity of incident light.

Referring to FIG. 4 and FIG. 5, the pixel separating pattern 450 may be disposed in the first substrate 400. The pixel separating pattern 450 may have a lattice structure in a plan view. As shown in FIG. 3, the pixel separating pattern 450 may be disposed in a lattice form in a region between the pixels PX. That is, the pixel separating pattern 450 may surround the respective pixels PX. The pixel separation pattern 450 disposed on the pixel array area AR and the pixel separation pattern 450 disposed on the optical black area OB may be formed through the same process. Additionally, the pixel separation pattern 450 disposed on the pixel array area AR and the pixel separation pattern 450 disposed on the optical black area OB may have the same width in the first direction (x-direction).

Referring to FIG. 4 and FIG. 5, the pixel separating pattern 450 may be disposed in a first trench TR1 and a second trench TR2. Referring to FIG. 5, the first trench TR1 and the second trench TR2 may be recessed from the first side 400a of the first substrate 400. The first trench TR1 may penetrate the first substrate 400, and the second trench TR2 may not penetrate the first substrate 400. That is, a depth of the first trench TR1 may be greater than a depth of the second trench TR2. The first trench TR1 may abut the second trench TR2.

The pixel separating pattern 450 may extend to the second side 400b from the first side 400a of the first substrate 400. The pixel separating pattern 450 may be a deep trench isolation (DTI) film. The pixel separating pattern 450 may penetrate the first substrate 400. A vertical height of the pixel separating pattern 450 may be substantially equivalent to a vertical thickness of the first substrate 400.

The pixel separating pattern 450 may include a first separating pattern 451, a second separating pattern 452, and a third separating pattern 453.

The first separating pattern 451 may include a first portion 451A disposed in the first trench TR1 and a second portion 451B disposed in the second trench TR2. The first portion 451A may be disposed along a sidewall of the first trench TR1, and the second portion 451B may fill the second trench TR2. In this instance, the second portion 451B of the first separating pattern 451 may be a shallow trench isolation (STI) film. The second portion 451B of the first separating pattern 451 may define an active pattern.

That is, the second portion 451B and the first portion 451A of the first separating pattern 451 may have a staircase structure. A depth of the second portion 451B of the first separating pattern 451 may be less than a depth of the first portion 451A of the first separating pattern 451.

The first separating pattern 451 may include a silicon-based insulating material (e.g., silicon nitride, silicon oxide, or silicon oxynitride). For example, the first separating pattern 451 may include silicon oxide.

The second separating pattern 452 may include a first portion 452A filling (a center region of) the first trench TR1 and a second portion 452B disposed along a sidewall of the first trench TR1 (or the first portion 451A of the first separating pattern 451).

The first separating pattern 451 may be disposed between the second separating pattern 452 and the first substrate 400. The second separating pattern 452 may be spaced from the first substrate 400 by the first separating pattern 451. Hence, when the image sensor is operated, the second separating pattern 452 may be electrically separated from the first substrate 400. The second separating pattern 452 may include a crystalline semiconductor material, for example, polysilicon. For example, the second separating pattern 452 may further include a dopant, and the dopant may include the impurities of the first conductive type or the impurities of the second conductive type.

For example, the second separating pattern 452 may include doped polysilicon. For another example, the second separating pattern 452 may include an undoped crystalline semiconductor material. For example, the second separating pattern 452 may include undoped polysilicon. The term “undoped” may represent that an intentional doping process is not performed. The dopant may include an n-type dopant and a p-type dopant.

The second separating pattern 452 may have conductivity. For example, the second separating pattern 452 may have electrical conductivity of 1.0×10⁻⁵ S/m (Siemens/meter) to 1.0×10⁵ S/m (Siemens/meter).

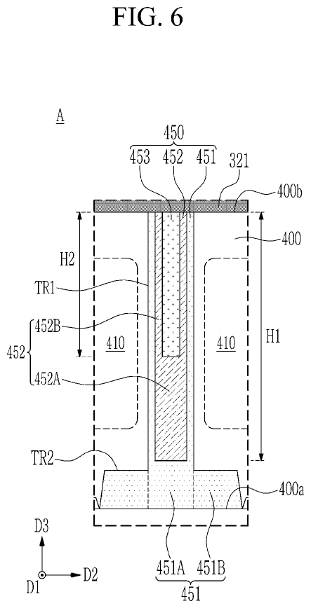

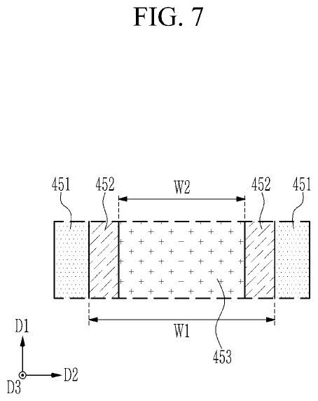

The third separating pattern 453 may fill the first trench TR1 and may be disposed in a region between (i.e. inside) the second portion 452B of the second separating pattern 452. As shown in FIG. 5, one edges of the first separating pattern 451, the second separating pattern 452, and the third separating pattern 453 may be disposed on the second side 400b of the first substrate 400. The present embodiment relates to a structure of the pixel separating pattern 450 and a formation method thereof, and a detailed stacking structure of the pixel separating pattern 450 will be described later with reference to FIG. 6 and FIG. 7.

The transmission transistor TX, the amplification transistor SX, the reset transistor RX, the dual conversion transistor DCX, and the selection transistor AX described with reference to FIG. 2 may be disposed on the first side 400a of the first substrate 400. The transmission transistor TX may be disposed on active patterns of the respective pixels PX. The transmission transistor TX may be electrically connected to the photoelectric conversion region 410. The transmission transistor TX may include a transmission gate TG and a floating diffusion region FD on the active patterns. The transmission gate TG may include a first portion TGa disposed on the first side 400a of the first substrate 400 and a second portion TGb extending into the first substrate 400 from the first portion TGa. A maximum width of the first portion TGa in the second direction D2 may be greater than a maximum width of the second portion TGb in the second direction D2. Also, the transmission gate TG may include a first portion TGa disposed on the first side 400a of the first substrate 400 and may not include a second portion TGb extending into the first substrate 400 from the first portion TGa. The floating diffusion region FD may be near one side of the transmission gate TG. The floating diffusion region FD may be disposed in the active pattern. The floating diffusion region FD may have the second conductive type (e.g., n-type) that is opposite the first substrate 400.

Referring to FIG. 2, the amplification transistor SX and the selection transistor AX may also be disposed on the first side 400a of the first substrate 400. That is, the gate electrode SF of the amplification transistor SX and the gate electrode AG of the selection transistor AX may be disposed on the first side 400a of the first substrate 400. The reset transistor RX and the dual conversion transistor DCX may be disposed on the first side 400a of the first substrate 400. The reset transistor RX may include a reset gate RG, and the dual conversion transistor DCX may include a dual conversion gate DCG.

A gate dielectric layer GI may be disposed between the respective transmission gate TG, a selection gate AG, an amplification gate SG, a dual conversion gate DCG, and a reset gate RG and the first substrate 400. A gate spacer GS may be disposed on sidewalls of the respective gate electrodes TG, AG, SG, DCG, and RG. The gate spacer GS may include, for example, silicon nitride, silicon carbonitride, or silicon oxynitride

However, in another embodiment, an opposing substrate overlapping the first substrate 400 may be further included, and at least one of the amplification transistor SX, the selection transistor AX, the reset transistor RX, and the dual conversion transistor DCX may be disposed on the opposing substrate. In this embodiment, at least one of the amplification transistor SX, the selection transistor AX, the reset transistor RX, and the dual conversion transistor DCX disposed on the second substrate and the transmission transistor TX disposed on the first substrate 400 may be connected by a connection node.

The first wire region 20 may be disposed on the first side 400a of the first substrate 400, and may include insulation layers IL1, IL2, and IL3, wiring layers CL1 and CL2, and a via VIA.

The insulation layers may include a first insulation layer IL1, a second insulation layer IL2, and a third insulation layer IL3.

The first insulation layer IL1 may cover the first side 400a of the first substrate 400. The first insulation layer IL1 may cover the gate electrode TG. The second insulation layer IL2 may be disposed on the first insulation layer IL1. The third insulation layer IL3 may be disposed on the second insulation layer IL2.

The first insulation layer to the third insulation layer IL1, IL2, and IL3 may include non-conductive materials. For example, the first insulation layer to the third insulation layer IL1, IL2, and IL3 may include silicon-based insulating materials such as silicon oxide, silicon nitride, or silicon oxynitride.

The first wire region 20 may include a first wiring layer CL1 and a second wiring layer CL2. The first wiring layer CL1 may be disposed in the second insulation layer IL2. The second wiring layer CL2 may be disposed in the third insulation layer IL3.

The vias VIA may be disposed in the first insulation layer IL1, the second insulation layer IL2, and the third insulation layer IL3. The vias VIA may connect the floating diffusion region FD, the first wiring layer CL1, and the second wiring layer CL2 to each other.

The first wiring layer CL1, the second wiring layer CL2, and the via VIA may include metallic materials. For example, the first wiring layer CL1, the second wiring layer CL2, and the via VIA may include copper (Cu).

The light transmitting layer 30 may include an insulation structure 329, a color filter 303, and a micro lens portion 306. The light transmitting layer 30 may collect light input from an outside, may filter the light, and may provide the filtered light to the photoelectric conversion region 410.

The color filter 303 may be disposed on the second side 400b of the first substrate 400. The color filter 303 may be disposed on the pixel PX. The color filter 303 may include primary color filters for each pixel PX. The color filter 303 may include a first color filter, a second color filter, and a third color filter, each having a different color. For example, the first color filter, the second color filter, and the third color filter may include a green color filter, a red color filter, and a blue color filter, respectively. The first color filter, the second color filter, and the third color filter may be arranged in a Bayer pattern method. For another example, the first color filter, the second color filter, and the third color filter may include colors such as cyan, magenta, or yellow.

The insulation structure 329 may be disposed between the second side 400b of the first substrate 400 and the color filter 303. The insulation structure 329 may prevent light from being reflected so that light input to the second side 400b of the first substrate 400 may smoothly reach the photoelectric conversion region 410. The insulation structure 329 may be referred to as an antireflection structure.

The insulation structure 329 may include a surface insulation layer 321, fixed charge film 323 and planarization layer 325 sequentially stacked on the second side 400b of the first substrate 400. The surface insulation layer 321, the fixed charge film 323, and the planarization layer 325 respective may include different materials.

For example, the surface insulation layer 321 may include at least one of silicon oxide, silicon nitride, silicon oxynitride, aluminum oxide, hafnium oxide, titanium oxide, tantalum oxide, and combinations thereof, and is not limited thereto. For example, the surface insulation layer 321 may include silicon oxide.

The fixed charge film 323 may include another one of the aluminum oxide, the tantalum oxide, the titanium oxide, and the hafnium oxide.

The planarization layer 325 may include at least one of the silicon oxide, silicon nitride, silicon oxynitride, aluminum oxide, hafnium oxide, titanium oxide, tantalum oxide, and combinations thereof, and is not limited thereto.

In another embodiment, a silicon antireflection layer may be provided between the fixed charge film 323 and the planarization layer 325. the antireflection layer may include silicon nitride.

At least one of the surface insulation layer 321, the fixed charge film 323, and the planarization layer 325 may be omitted according to the embodiment. That is, the surface insulation layer 321 may be disposed on the second side 400b of the first substrate 400, or the planarization layer 325 may be disposed on the second side 400b of the first substrate 400.

The micro lens portion 306 may be disposed on the color filter 303. The micro lens portion 306 may include a planarizer 305 contacting the color filter 303 and a micro lens 307 disposed on the planarizer 305. The planarizer 305 may, for example, include an organic material. For another example, the planarizer 305 may include silicon oxide or silicon oxynitride. The micro lens 307 may have a convex shape for collecting light input to the pixel PX. The respective micro lenses 307 may vertically overlap the photoelectric conversion region 410. The shape of the lens may be various. FIG. 5 shows that one micro lens 307 overlaps one photoelectric conversion region 410, and one micro lens 307 may overlap photoelectric conversion regions 410.

The light transmitting layer 30 may further include a low-refraction pattern 311 and a protective layer 316. The low-refraction pattern 311 may be disposed between the color filters 303 that are adjacent to each other and may separate them. The low-refraction pattern 311 may be disposed on the insulation structure 329. For example, the low-refraction pattern 311 may have a lattice structure. The low-refraction pattern 311 may include a material having a lower refractive index than the color filter 303. The low-refraction pattern 311 may include an organic material. For example, the low-refraction pattern 311 may be a polymer layer including silica nanoparticles. The low-refraction pattern 311 has a low refractive index so it may increase an amount of light input to the photoelectric conversion region 410, and may reduce crosstalk among the pixels PX. That is, light receiving efficiency may be increased in the photoelectric conversion regions 410, and a signal-to-noise ratio (SNR) characteristic may be improved.

The protective layer 316 may cover a surface of the low-refraction pattern 311 with a substantially uniform thickness. The protective layer 316 may, for example, include a single layer of at least one of an aluminum oxide layer and a silicon carbonized oxide layer, or a multilayer thereof. The protective layer 316 may protect the color filter 303 and may absorb moisture.

Referring to FIG. 4, the image sensor may further include a logic chip 2000. The logic chip 2000 may be stacked on the sensor chip 1000. The logic chip 2000 may include a second substrate 500 and a second wire region 40. The second wire region 40 may be disposed between the first wire region 20 and the second substrate 500.

Referring to FIG. 4, the pixel array region AR may include pixels PX. Descriptions on the pixel array region AR correspond to what is described with reference to FIG. 2 to FIG. 5. The optical black region OB and the pad region PAD will now be described with major reference to FIG. 4.

A first connection structure 50, a first pad terminal 81, and a bulk color filter 90 may be disposed on the first substrate 400 in the optical black region OB. The first connection structure 50 may include a first light blocking pattern 51, a first insulation pattern 53, and a first capping pattern 55. The first light blocking pattern 51 may be disposed on the second side 400b of the first substrate 400. The first light blocking pattern 51 may uniformly cover interior walls of a third trench TR3 and a fourth trench TR4. The first light blocking pattern 51 may penetrate the photoelectric conversion layer 10 and the first wire region 20 and may electrically connect the photoelectric conversion layer 10 and the first wire region 20. In further detail, the first light blocking pattern 51 may contact the wire in the first wire region 20 and the pixel separating pattern 450 in the photoelectric conversion layer 10. Accordingly, the first connection structure 50 may be electrically connected to the wires in the first wire region 20. The first light blocking pattern 51 may include a metallic material, for example, tungsten. The first light blocking pattern 51 may block the light input to the optical black region OB.

The first pad terminal 81 may be disposed inside the third trench TR3 and may fill a remaining portion of the third trench TR3. The first pad terminal 81 may include a metallic material, for example, aluminum. The first pad terminal 81 may be connected to the pixel separating pattern 450. In further detail, the first pad terminal 81 may be connected to the second separating pattern 452. Hence, a negative voltage may be applied to the pixel separating pattern 450 through the first pad terminal 81. As described above with reference to FIG. 5, a first end of the second separating pattern 452 is disposed on the second side 400b of the first substrate 400 so the second separating pattern 452 may receive a voltage through the first pad terminal 81.

The first insulation pattern 53 may be disposed on the first light blocking pattern 51 and may fill another portion of the fourth trench TR4. The first insulation pattern 53 may penetrate the photoelectric conversion layer 10 and the first wire region 20. The first capping pattern 55 may be disposed on the first insulation pattern 53. The first capping pattern 55 may be disposed on the first insulation pattern 53.

The bulk color filter 90 may be disposed on the first pad terminal 81, the first light blocking pattern 51, and the first capping pattern 55. The bulk color filter 90 may cover the first pad terminal 81, the first light blocking pattern 51, and the first capping pattern 55. The first protective layer 71 may be disposed on the bulk color filter 90 to cover the bulk color filter 90

A photoelectric conversion region 410′ and a dummy region 411 may be disposed in the optical black region OB of the first substrate 400. The photoelectric conversion region 410′ may, for example, be doped with impurity in the second conductive type that is different from the first conductive type. The second conductive type may, for example, be an n-type. The photoelectric conversion region 410′ may have a similar structure to the photoelectric conversion region 410 described with reference to FIG. 5, and may not perform an operation for receiving light and generating electrical signals. The dummy region 411 may be a region to which no impurities are doped. The signals generated by the photoelectric conversion region 410′ and the dummy region 411 may be used as information for removing processing noise.

A second connection structure 60, a second pad terminal 83, and a second protective layer 73 may be disposed on the first substrate 400 in the pad region PAD. The second connection structure 60 may include a second light blocking pattern 61, a second insulation pattern 63, and a second capping pattern 65.

The second light blocking pattern 61 may be disposed on the second side 400b of the first substrate 400. In further detail, the second light blocking pattern 61 may uniformly cover interior walls of the fifth trench TR5 and the sixth trench TR6. The second light blocking pattern 61 may penetrate part of the photoelectric conversion layer 10, the first wire region 20, and the second wire region 40. In further detail, the second light blocking pattern 61 may contact wires 231 and 232 in the second wire region 40. The second light blocking pattern 61 may include a metallic material, for example, tungsten.

The second pad terminal 83 may be disposed in the fifth trench TR5. The second pad terminal 83 may be disposed on the second light blocking pattern 61 and may fill a remaining portion of the fifth trench TR5. The second pad terminal 83 may include a metallic material, for example, aluminum. The second pad terminal 83 may function as an electrical connection passage between the image sensor element and the outside. The second insulation pattern 63 may fill a remaining portion of the sixth trench TR6. The second insulation pattern 63 may penetrate the whole photoelectric conversion layer 10 and the first wire region 20 or part thereof. The second capping pattern 65 may be disposed on the second insulation pattern 63. The second protective layer 73 may cover a portion of the second light blocking pattern 61 and the second capping pattern 65.

A current applied through the second pad terminal 83 may flow to the pixel separating pattern 450 through the second light blocking pattern 61, the wires 231 and 232 in the second wire region 40, and the first light blocking pattern 51. The electrical signals generated by the photoelectric conversion regions 410 and 410′ and the dummy region 411 may be transmitted to the outside through the wires of the first wire region 20, the wires 231 and 232 in the second wire region 40, the second light blocking pattern 61, and the second pad terminal 83.

A stacking structure of the pixel separating pattern 450 of the image sensor according to the present embodiment will now be described with reference to FIG. 6.

FIG. 6 shows an enlarged portion marked as A in FIG. 5. Referring to FIG. 6, the pixel separating pattern 450 may include a first separating pattern 451, a second separating pattern 452, and a third separating pattern 453.

Referring to FIG. 6, the first trench TR1 and the second trench TR2 may be disposed on the first side 400a of the first substrate 400. The first trench TR1 may penetrate the first substrate 400, and the second trench TR2 may not penetrate the first substrate 400. That is, as shown in FIG. 6, a depth of the second trench TR2 may be less than a depth of the first trench TR1.

The first separating pattern 451 may be disposed in the first trench TR1 and the second trench TR2. That is, the first separating pattern 451 may include a first portion 451A disposed in the first trench TR1 and a second portion 451B disposed in the second trench TR2.

The first portion 451A of the first separating pattern 451 may be disposed along the sidewall of the first trench TR1. In this instance, a thickness of the first separating pattern 451 disposed on the sidewall of the first trench TR1 may be 10 nm to 30 nm, which is an example and to which the disclosure is not limited.

As shown in FIG. 6, the second portion 451B and the first portion 451A of the first separating pattern 451 may have a staircase structure. A depth of the first portion 451A of the first separating pattern 451 in a third direction D3 may be greater than a depth of the second portion 451B in the third direction D3. As shown in FIG. 6, the first separating pattern 451 may be disposed on the first side 400a of the first substrate 400.

An edge of the first separating pattern 451 disposed along the sidewall of the first trench TR1 may be disposed on the second side 400b of the first substrate 400.

The first separating pattern 451 may include a silicon-based insulating material (e.g., silicon nitride, silicon oxide, or silicon oxynitride). For example, the first separating pattern 451 may include silicon oxide. FIG. 6 shows that the first portion 451A and the second portion 451B of the first separating pattern 451 includes the same material, and depending on the embodiments, the first separating pattern 451 may include different materials for respective regions.

Referring to FIG. 6, the second separating pattern 452 may be disposed in the first trench TR1. As shown in FIG. 6, the second separating pattern 452 may include a first portion 452A for filling a space in the first trench TR1 and a second portion 452B disposed along the sidewall of the first trench TR1.

The first portion 451A of the first separating pattern 451 may be disposed between the second separating pattern 452 and the first substrate 400. The second separating pattern 452 may be spaced from the first substrate 400 by the first separating pattern 451. Accordingly, when the image sensor is operated, the second separating pattern 452 may be electrically separated from the first substrate 400.

The second separating pattern 452 may include a crystalline semiconductor material, for example, polysilicon. For example, the second separating pattern 452 may further include a dopant, and the dopant may include impurities of a first conductive type or impurities of a second conductive type.

For example, the second separating pattern 452 may include doped polysilicon. For another example, the second separating pattern 452 may include an undoped crystalline semiconductor material. For example, the second separating pattern 452 may include undoped polysilicon. The term “undoped” may represent that an intentional doping process is not performed. The dopant may include an n-type dopant and a p-type dopant.

The first portion 452A of the second separating pattern 452 may fill an inside of the first trench TR1. However, the first portion 452A of the second separating pattern 452 may not fill the entire first trench TR1 but may fill a part thereof. The first trench TR1 that is not filled with the second separating pattern 452 may be filled with the third separating pattern 453.

Referring to FIG. 6, the first portion 452A of the second separating pattern 452 may be connected to the second portion 452B disposed along the sidewall of the first trench TR1, and one edge of the second portion 452B of the second separating pattern 452 may be disposed on the second side 400b of the first substrate 400. Therefore, the voltage may be applied to the second separating pattern 452 from the second side 400b of the first substrate 400.

That is, as described above, the second separating pattern 452 may have conductivity. By applying the voltage to the second separating pattern 452 that has conductivity, a dark current may be prevented from being generated in the image sensor. The dark current may be generated by electrons that are generated when no light is applied in the photoelectric region of the first substrate 400. In this instance, generation of the dark current may be prevented by moving the electrons generated by applying the voltage to the second separating pattern 452 in the direction of the pixel separating pattern 450.

The third separating pattern 453 may be disposed in the first trench TR1 that is not filled with the second separating pattern 452. That is, the third separating pattern 453 may overlap the first portion 452A of the second separating pattern 452 in the third direction D3.

The third separating pattern 453 may include a silicon-based insulating material (e.g., silicon nitride, silicon oxide, or silicon oxynitride). The third separating pattern 453 may include a material that is different from the first separating pattern 451. For example, when the first separating pattern 451 includes silicon oxide, the third separating pattern 453 may include silicon nitride. When the first separating pattern 451 includes silicon nitride, the third separating pattern 453 may include silicon oxide. Therefore, the first separating pattern 451 may not be etched together in an etching process for forming the third separating pattern 453. However, when the first separating pattern 451 is covered by the second separating pattern 452 in the process for etching the third separating pattern 453, the first separating pattern 451 and the third separating pattern 453 may include the same material. That is, the first separating pattern 451 and the third separating pattern 453 may include silicon nitride, or they may include silicon oxide.

A length H2 of the third separating pattern 453 in the third direction D3 to an entire length H1 of the second separating pattern 452 in the third direction D3 may be equal to or less than 70% of the entire length H1 of the second separating pattern 452 in the third direction D3. When the length H2 of the third separating pattern 453 is greater than 70% of the entire length H1 of the second separating pattern 452, a region occupied by the second separating pattern 452 is reduced so the effect of removing the dark current by applying the voltage of the second separating pattern 452 may be reduced. The length H2 of the third separating pattern 453 may be equal to or greater than 1 μm. When the length of the third separating pattern 453 is shorter than 1 μm, sensitivity of the image sensor may be deteriorated by the second separating pattern 452 that has conductivity.

The first end of the third separating pattern 453 may be disposed on the second side 400b of the first substrate 400. That is, as shown in FIG. 6, first ends of the first separating pattern 451, the second separating pattern 452, and the third separating pattern 453 may be disposed on the second side 400b of the first substrate 400. In FIG. 5 and FIG. 6, the second separation pattern 452 is shown as a flat surface at the contact surface between the first separation pattern 451 and the second separation pattern 452, but the surface of the second separation pattern 452 at the contact surface between the first separation pattern 451 and the second separation pattern 452 may be curved.

FIG. 7 shows a partial shape of a pixel separating pattern 450 on a second side 400b of a first substrate 400 in a plan view. As shown in FIG. 7, the pixel separating pattern 450 is disposed on the second side 400b of the first substrate 400, and first ends of the first separating pattern 451, the second separating pattern 452, and the third separating pattern 453 may be disposed thereon.

That is, the first separating pattern 451 that is an insulation layer, the second separating pattern 452 that is a conductive layer, and the third separating pattern 453 that is an insulation layer are disposed on the second side 400b. As the first end of the second separating pattern 452 is exposed on the second side 400b of the first substrate 400, the voltage may be easily applied to the second separating pattern 452.

In this instance, as shown in FIG. 7, a ratio of a portion occupied by a width W2 of the third separating pattern 453 to a sum W1 of widths of the second separating pattern 452 and the third separating pattern 453 in the second direction D2 may be 50% to 95%. When the ratio is less than 50%, the sensitivity of the image sensor may be deteriorated by the conductive second separating pattern 452, and when the ratio is greater than 95%, the area of the second separating pattern 452 in a plan view is reduced, and the area for applying the voltage to the second separating pattern 452 may be insufficient. Further, resistance may increase when the voltage is applied to the second separating pattern 452.

As described, the pixel separating pattern 450 of the image sensor according to the present embodiment has a structure in which the first ends of the first separating pattern 451, the second separating pattern 452, and the third separating pattern 453 are disposed on the second side 400b of the first substrate 400. Therefore, the voltage may be easily applied to the second separating pattern 452. Further, regarding the pixel separating pattern 450 of the image sensor according to the present embodiment, the conductive second separating pattern 452 and the non-conductive third separating pattern 453 are disposed in the first trench TR1. Therefore, the problem that the sensitivity of the image sensor is deteriorated by the conductive second separating pattern 452 when the first trench TR1 is filled with the conductive second separating pattern 452 may be solved. That is, the pixel separating pattern 450 of the image sensor is formed to have a multilayer including the second separating pattern 452 and the third separating pattern 453, thereby removing the dark current and preventing the sensitivity of the image sensor from being deteriorated. Further, as the first separating pattern 451 and the third separating pattern 453 include different materials, the first separating pattern 451 may be prevented from being etched in the process for forming the third separating pattern 453.

FIG. 6 shows the pixel separating pattern 450 in a structure in which the first separating pattern 451, the second separating pattern 452, and the third separating pattern 453 are included in the first trench TR1, and in another embodiment, part of the surface insulation layer 321 may be further included in the first trench TR1.

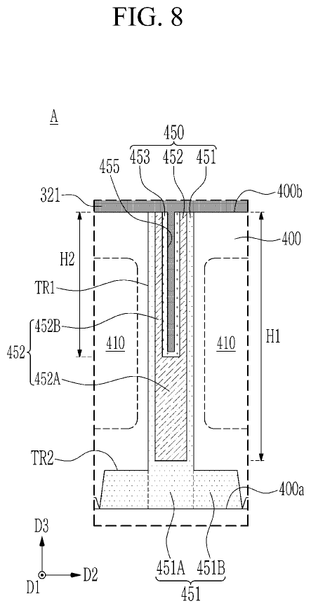

FIG. 8 shows a same portion as FIG. 6 according to another embodiment. Referring to FIG. 8, regarding the pixel separating pattern 450, the third separating pattern 453 may not fill the entire first trench TR1 and may include a void 455. In this instance, the void 455 may be filled with the surface insulation layer 321. The surface insulation layer 321 may include at least one of silicon oxide, silicon nitride, silicon oxynitride, aluminum oxide, hafnium oxide, titanium oxide, tantalum oxide, and combinations thereof, and is not limited thereto. For example, the surface insulation layer 321 may include silicon oxide.

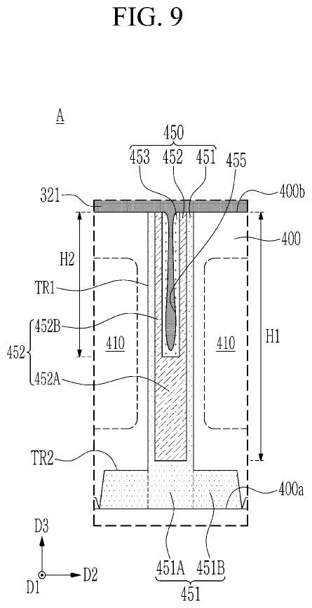

In the embodiment of FIG. 8, the void 455 is shown to be linear, which is however an example, and the shape of the void 455 is not limited thereto. FIG. 9 shows a same portion as FIG. 6 according to another embodiment. Referring to FIG. 9, the image sensor according to the present embodiment corresponds to what is described with reference to FIG. 8, except the shape of the void 455 of the third separating pattern 453. No same constituent elements will be described in detail. Referring to FIG. 9, the void 455 of the third separating pattern 453 has a lump shape occupying a predetermined volume, which is different from the linear shape of FIG. 8, and the void 455 may be filled by the surface insulation layer 321.

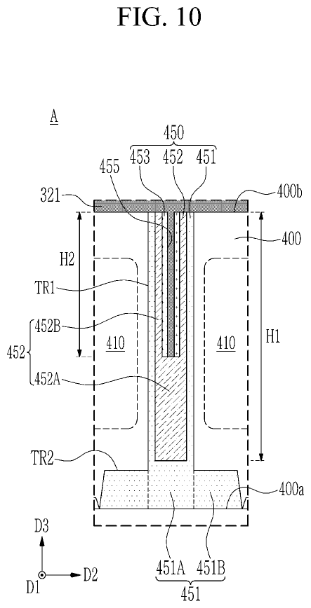

FIG. 10 shows a same portion as FIG. 6 according to another embodiment. Referring to FIG. 10, the image sensor corresponds to what is described with reference to FIG. 8 except the shape of the void 455 of the third separating pattern 453. No same constituent elements will be described in detail. Referring to FIG. 10, the void 455 may be formed to be longer than the embodiment of FIG. 8 and may penetrate the third separating pattern 453. That is, as shown in FIG. 10, the void may penetrate the third separating pattern 453 in the third direction D3, and the surface insulation layer 321 filled in the void 455 may directly contact the second separating pattern 452. As shown in FIG. 10, an upper side of the first portion 452A of the second separating pattern 452 may directly contact the surface insulation layer 321. However, the shape of the void 455 shown in FIG. 8 to FIG. 10 is examples, and the actual shape of the void 455 may be various. That is, FIG. 8 and FIG. 10 show that the void 455 has a uniform shape, and the actual void 455 may have different sizes or widths for respective regions. Further, FIG. 9 shows that the void 455 has an increasing width in accordance with a distance to the first side 400a of the first substrate 400, and the void 455 may have an increasing width in accordance with a distance to the second side 400b of the first substrate 400.

The void 455 of the third separating pattern 453 of FIG. 8 to FIG. 10 may be formed as the third separating pattern 453 fails to sufficiently fill the first trench TR1 in the process for forming the third separating pattern 453. That is, the first trench TR1 has a depth that is greater than the width so a portion in which the third separating pattern 453 is not filled may be generated in the first trench TR1, and the portion in which the third separating pattern 453 is not formed may become the void 455.

A method for manufacturing an image sensor according to the present embodiment will now be described with a focus on the process for forming the pixel separating pattern 450.

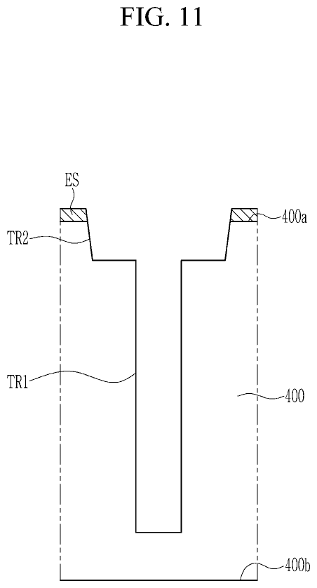

FIG. 11 to FIG. 21 shows a process for manufacturing an image sensor according to a present embodiment. FIG. 11 to FIG. 21 show a manufacturing process on a same region as FIG. 6.

Referring to FIG. 11, a first substrate 400 including a first side 400a and a second side 400b facing each other is provided. The first substrate 400 may include impurities of a first conductive type (e.g., p-type). For example, the first substrate 400 may be provided by forming an epitaxial layer of a first conductive type on the bulk silicon substrate of a first conductive type. For another example, the first substrate 400 may be a bulk substrate including a well of a first conductive type.

Referring to FIG. 11, the first substrate 400 may include a first trench TR1 and a second trench TR2. An etch stopper layer ES may be disposed on the first side 400a of the first substrate 400. The etch stopper layer ES may be an inorganic insulation layer, and for example, it may include silicon nitride. To be described in a subsequent process, the etch stopper ES may be used as an etch stopper in the process for etching the first side 400a.

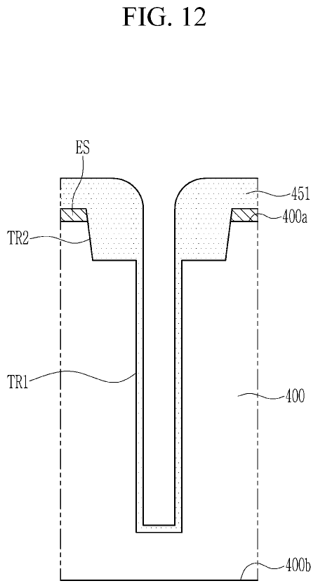

Referring to FIG. 12, a first separating pattern 451 may be formed on the first side 400a of the first substrate 400. The first separating pattern 451 may include a silicon-based insulating material (e.g., silicon nitride, silicon oxide, or silicon oxynitride). For example, the first separating pattern 451 may include silicon oxide.

In this instance, the first separating pattern 451 may fill the entire region of the second trench TR2 and the sidewall of the first trench TR1. That is, by forming the first separating pattern 451, a lateral step between the first trench TR1 and the second trench TR2 may be filled, and the first separating pattern 451 may form a uniform sidewall. In the present stage, the first separating pattern 451 may not fill the entire first trench TR1 and may be formed on a side, or an edge of first trench TR1. For example, the thickness of the first separating pattern 451 formed in the first trench TR1 may be 10 nm to 30 nm, which is an example, and the disclosure is not limited thereto.

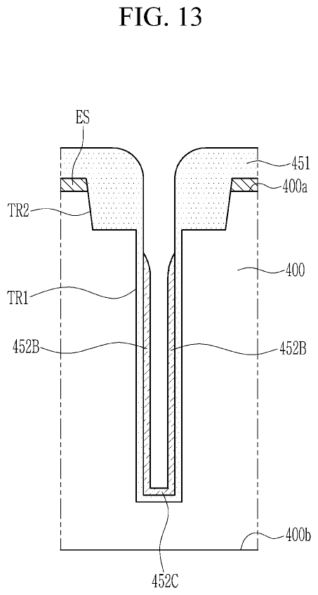

Referring to FIG. 13, a second portion 452B and a third portion 452C of the second separating pattern 452 may be formed in the first trench TR1. That is, the second separating pattern 452 may be disposed on a lower side and a lateral side of the first trench TR1, or on an edge of the first separating pattern 451. According to the embodiment, the second separating pattern 452 may be disposed on the lateral side of the first trench TR1 and not on the lower side, and in this case, the second portion 452B may be formed. As shown in FIG. 13, the second separating pattern 452 may be disposed not on the entire sidewall of the first trench TR1 but on part of the sidewall. This may be formed by a method for depositing the material of the second separating pattern 452 on the first trench TR1 and performing an etching process. The etching may be a dry etching.

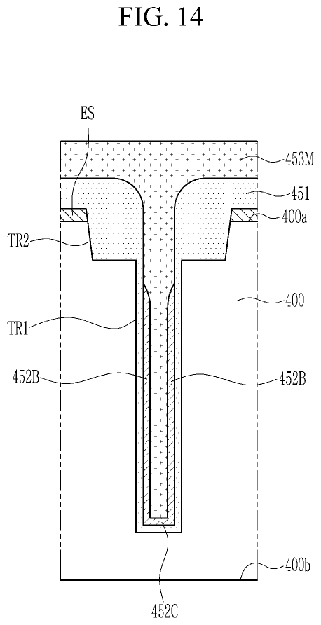

Referring to FIG. 14, a third separating pattern material 453M is formed in the first trench TR1 and on an upper side of the first separating pattern 451. In this instance, the third separating pattern material 453M may include a silicon-based insulating material (e.g., silicon nitride, silicon oxide, or silicon oxynitride). However, the third separating pattern material 453M may include a material that is different from the first separating pattern 451. For example, when the first separating pattern 451 includes silicon oxide, the third separating pattern material 453M may include silicon nitride. Alternatively, when the first separating pattern 451 includes silicon nitride, the third separating pattern material 453M may include silicon oxide. This is to prevent the first separating pattern 451 from being etched when the third separating pattern material 453M is etched. That is, when the third separating pattern material 453M and the first separating pattern 451 includes the same material, the first separating pattern 451 may be etched in the process for etching the third separating pattern material 453M.

As shown in FIG. 14, the third separating pattern material 453M may fill the first trench TR1, and may cover the upper side of the first separating pattern 451. However, depending on the embodiments, the third separating pattern material 453M may not fill the entire first trench TR1, and in this case, as shown in FIG. 8 to FIG. 10, the third separating pattern 453 may include the void 455, and the pixel separating pattern 450 in a shape in which the void 455 is filled with the surface insulation layer 321 may be formed. In the present embodiment, the method for forming an image sensor in a shape shown in FIG. 6 is mainly described, and the manufacturing method according to the present embodiment may also be applied to the image sensor of FIG. 8 to FIG. 10.

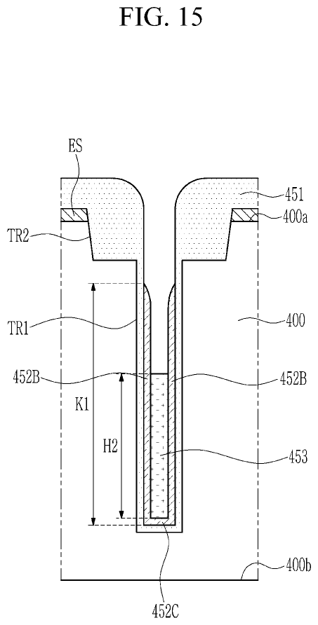

Referring to FIG. 15, the third separating pattern material 453M may be etched. The third separating pattern 453 may be formed by etching the third separating pattern material 453M. The third separating pattern material 453M disposed in the first trench TR1 is partly removed by etching the third separating pattern material 453M in the present stage. Therefore, as shown in FIG. 15, the length H2 of the third separating pattern 453 may be less than the length K1 of the second separating pattern 452.

By the etching of the present stage, part of the second portion 452B of the second separating pattern 452 may not be covered by the third separating pattern 453 but may be exposed.

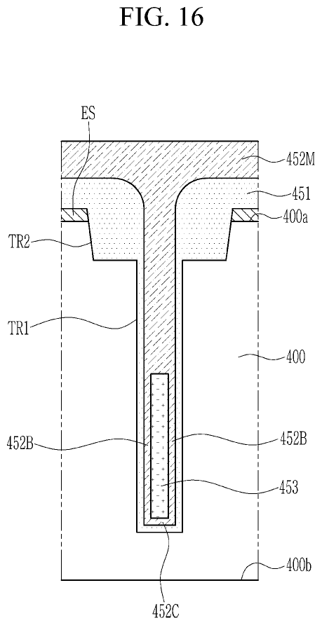

Referring to FIG. 16, the second separating pattern material 452M is deposited. In this instance, the second separating pattern material 452M may include the same material as the second portion 452B and the third portion 452C of the second separating pattern 452 formed in the previous stage. Therefore, a border between the second separating pattern 452 formed in the previous stage and the second separating pattern material 452M formed in the present stage may be invisible. As shown in FIG. 16, the second separating pattern material 452M may fill the first trench TR1 and may cover the upper portion of the first separating pattern 451.

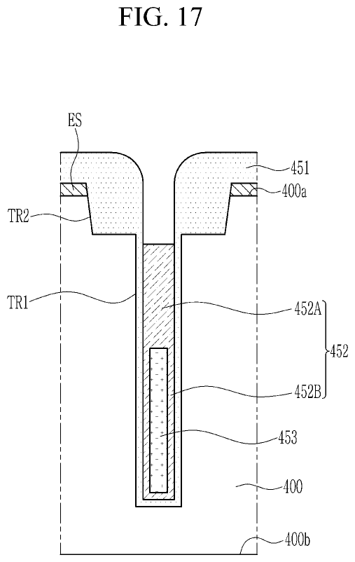

Referring to FIG. 17, the first portion 452A of the second separating pattern 452 is formed by etching the second separating pattern material 452M. The etching may include a dry etching. As shown in FIG. 17, the first portion 452A of the second separating pattern 452 may be disposed to be distant from the first side 400a of the first substrate 400 than the second trench TR2.

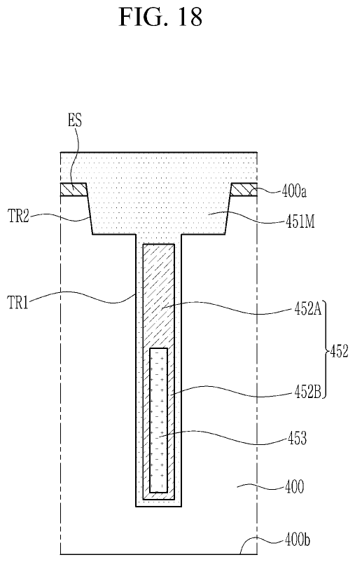

Referring to FIG. 18, an empty space of the first trench TR1 is filled by forming the first separating pattern material 451M. In this instance, as the first separating pattern material 451M includes the same material as the first separating pattern 451, the border with the first separating pattern 451 formed in the previous stage may be invisible. However, according to the embodiment, the first separating pattern material 451M in the present stage may include a different material from the first separating pattern 451 formed in the previous stage. In this case, the first separating pattern material 451M formed in the present stage may be distinguished from the previously formed first separating pattern 451.

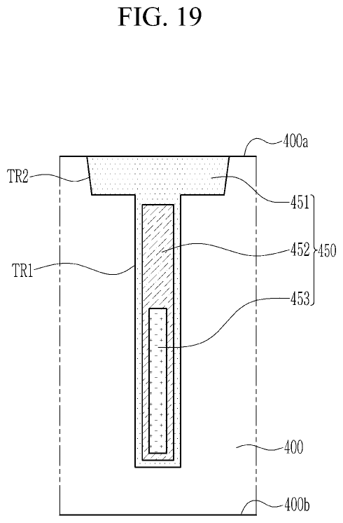

Referring to FIG. 19, the first side 400a of the first substrate 400 is etched. In this instance, the etch stopper layer ES may be etched in the etching process. As shown in FIG. 19, by the etching in the present stage, the first side 400a of the first substrate 400 may not be covered by the first separating pattern 451 and may be exposed. As shown in FIG. 19, the first side 400a of the first substrate 400 and the first separating pattern 451 may be disposed on the same side.

In FIG. 11 to FIG. 19, the bottom surface of the first trench TR1 is shown as a flat surface, which is an example, and the bottom surface of the first trench TR1 may be curved.

Accordingly, in the first trench TR1, the bottom surface of the first separation pattern 451 the bottom surface of the second separation pattern 452, and the bottom surface of the third separation pattern 453 may also be curved.

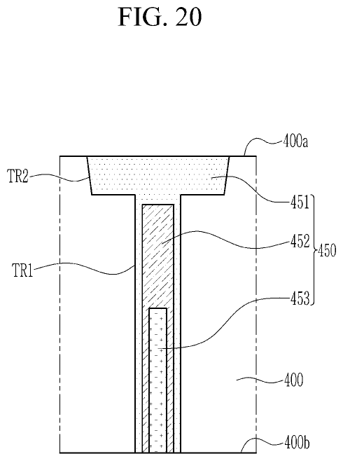

Referring to FIG. 20, the second side 400b of the first substrate 400 is etched. The etching in the present stage may be performed until the first ends of the first separating pattern 451, the second separating pattern 452, and the third separating pattern 453 are exposed on the second side 400b. That is, by the etching in the present stage, the third portion 452C of the second separating pattern 452 may be removed, and the pixel separating pattern 450 may be exposed on the second side 400b of the first substrate 400.

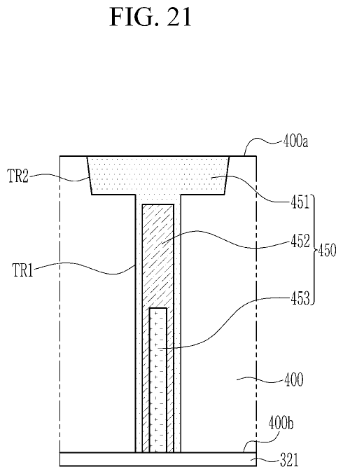

Referring to FIG. 21, the surface insulation layer 321 may be formed on the second side 400b of the first substrate 400. FIG. 21 shows that the surface insulation layer 321 is not disposed in the first trench TR1, and when the void 455 is formed as shown in FIG. 8 to FIG. 10 in the stage for forming the third separating pattern 453 of FIG. 14, the surface insulation layer 321 may be formed while filling the void 455.

According to the image sensor and the manufacturing method thereof according to the present embodiment, the pixel separating pattern has a structure in which the conductive and non-conductive films overlap each other in the thickness direction of the substrate. Therefore, the dark current may be reduced by the conductive region of the pixel separating pattern, and the deterioration of sensitivity may be prevented by the non-conductive region of the pixel separating pattern. Further, the first end of the conductive region is disposed on one side of the substrate so the voltage may be supplied to the conductive region.

While certain example embodiments of the disclosure have been particularly shown and described, it will be understood that various changes in form and details may be made therein without departing from the spirit and scope of the following claims.

What is claimed is:

1. An image sensor comprising:
a substrate comprising a first side and a second side facing the first side;
pixels comprising a photoelectric conversion layer in the substrate and a transistor on the first side of the substrate; and
a pixel separating pattern between the pixels,
wherein the pixel separating pattern comprises a first separating pattern, a second separating pattern, and a third separating pattern,
wherein the second separating pattern is conductive, and the first separating pattern and the third separating pattern are non-conductive,
wherein the second separating pattern is nearer the first side of the substrate than is the third separating pattern, and
wherein a first end of the first separating pattern, a first end of the second separating pattern, and a first end of the third separating pattern are on the second side of the substrate.

2. The image sensor of claim 1, further comprising:
a first trench penetrating the first side and the second side of the substrate; and
a second trench on the first side of the substrate and abutting the first trench,
wherein the first separating pattern comprises a first portion along an edge of the first trench and a second portion in the second trench.

3. The image sensor of claim 2, wherein the second separating pattern is in the first trench, and
wherein the first separating pattern is between the second separating pattern and the substrate.

4. The image sensor of claim 3, wherein the second separating pattern comprises a first portion filling a center region of the first trench and a second portion along the first portion of the first separating pattern.

5. The image sensor of claim 4, wherein the third separating pattern is disposed in a region inside the second portion of the second separating pattern, and
wherein the third separating pattern overlaps the first portion of the second separating pattern in a thickness direction of the substrate.

6. The image sensor of claim 5, wherein a length of the third separating pattern in the thickness direction of the substrate is equal to or greater than 1 μm.

7. The image sensor of claim 5, wherein a length of the third separating pattern in the thickness direction of the substrate is equal to or less than 70% of a length of the second separating pattern in the thickness direction of the substrate.

8. The image sensor of claim 1, wherein the first separating pattern and the third separating pattern comprise different materials.

9. The image sensor of claim 1, wherein the first separating pattern comprises silicon oxide,
wherein the second separating pattern comprises polysilicon, and
wherein the third separating pattern comprises silicon nitride.

10. The image sensor of claim 1, wherein the first separating pattern and the third separating pattern comprise a same material.

11. The image sensor of claim 1, further comprising:
a surface insulation layer on the second side of the substrate.

12. The image sensor of claim 11, wherein the third separating pattern further comprises a void, and
wherein the void is filled with the surface insulation layer.

13. An image sensor comprising:
a substrate comprising a first side and a second side facing the first side;
pixels each comprising a photoelectric conversion layer in the substrate and a transistor on the first side of the substrate; and
a pixel separating pattern between the pixels,
wherein the pixel separating pattern comprises a first separating pattern comprising silicon oxide, a second separating pattern comprising a polycrystalline semiconductor, and a third separating pattern comprising silicon nitride,
wherein the second separating pattern is nearer the first side of the substrate than is the third separating pattern, and
wherein edges of the third separating pattern, the second separating pattern on edges of the third separating pattern, and the first separating pattern contacting the second separating pattern are on the second side of the substrate.

14. The image sensor of claim 13, further comprising:
a first trench penetrating the substrate and a second trench on the first side of the substrate and abutting the first trench,
wherein the first separating pattern comprises a first portion along an edge of the first trench and a second portion in the second trench,
the second separating pattern comprises a first portion filling a center region of the first trench and a second portion along the first portion of the first separating pattern, and
the third separating pattern is in a region inside the second portion of the second separating pattern.

15. The image sensor of claim 13, wherein the first separating pattern, the second separating pattern, and the third separating pattern overlap each other in a thickness direction of the substrate.

16. The image sensor of claim 13, wherein on the second side of the substrate, a ratio of a width of the third separating pattern to a sum of a width of the second separating pattern and the width of the third separating pattern is 50% to 95%.

17. A method for manufacturing an image sensor, the method comprising:
providing a substrate comprising a first side, a second side, and a first trench disposed on the first side;
forming a first separating pattern on an edge of the first trench of the substrate;
forming a second portion of a second separating pattern in the first trench on the first separating pattern;
forming a third separating pattern in the first trench;
forming a first portion of the second separating pattern overlapping the third separating pattern in a thickness direction of the substrate in the first trench;
etching the first side; and
etching the second side,
wherein the etching of the second side comprises exposing a first end of the first separating pattern, a first end of the second separating pattern, and a first end of the third separating pattern on the second side of the substrate.

18. The method of claim 17, further comprising:
forming a transistor on the first side, and
forming a surface insulation layer on the second side.

19. The method of claim 17, wherein the first separating pattern, the second separating pattern, and the third separating pattern overlap each other in the thickness direction of the substrate.

20. The method of claim 17, wherein the first separating pattern comprises silicon oxide,
wherein the second separating pattern comprises polysilicon, and
wherein the third separating pattern comprises silicon nitride.
